(19) United States
(12) Patent Application Publication
(10) Pub. No.: US 2012/0174962 A1
(43) Pub. Date: Jul. 12, 2012

(54) Controlling Movement of a Solar Energy Member

(75) Inventors: Ross Koningstein, Menlo Park, CA (US); Benjamin M. Davis, San Francisco, CA (US); Timothy Peter Allen, Santa Cruz, CA (US); Jung Shia Gwon, Santa Cruz, CA (US)

(73) Assignee: Google Inc., Mountain View, CA (US)

(21) Appl. No.: 13/209,823

(22) Filed: Aug. 15, 2011

Related U.S. Application Data
(60) Provisional application No. 61/430,233, filed on Jan. 6, 2011.

(51) Int. Cl. H01L 31/052; F24J 2/52; F24J 2/16; F24J 2/38

(52) U.S. Cl. 136/246; 126/600; 126/605; 126/574

(57) ABSTRACT

A solar energy system includes a support member secured to a substantially fixed location; a solar energy member mounted to the support member and including a surface operable to track in response to movement of the Sun; an actuator assembly coupled to the solar energy member and configured to periodically apply a torque at a first frequency to move the solar energy member in response to movement of the Sun; and a damper assembly including a spool, where the damper assembly is configured to reactively release and retract a cable about the spool in response to changes in the steady state load, and maintain the cable at a substantially fixed length released from the spool in response to a torque at a second frequency greater than the first frequency that is intermittently received by the solar energy member.

### CLAIM OF PRIORITY

This application claims priority under 35 U.S.C. §119(e) to U.S. Provisional Patent Application Ser. No. 61/430,233 filed on Jan. 6, 2011, entitled “SYSTEMS AND METHODS FOR SOLAR ENERGY MANAGEMENT,” the entire contents of which are hereby incorporated by reference.

### TECHNICAL BACKGROUND

This disclosure relates to systems and methods for controlling movement of a solar energy member of a solar energy system.

### BACKGROUND

Solar energy management, collection, and use can often help alleviate energy problems around the world. In particular, solar energy systems such as photovoltaic (“PV”) systems, which generate electrical energy from solar energy can reduce dependence on fossil fuels or other power generation techniques. Additionally, solar energy may be used to generate heat that can subsequently be used in power generation systems. In some cases, solar energy collection systems may include multiple heliostats that reflect solar energy to a receiver. The receiver may then use solar energy for one or more purposes. In some instances, heliostats are tracking mirrors, which reflect and focus sunlight onto a distant target, such as the receiver.

For optimal operation, heliostats move precisely and maintain a precise aiming angle, even when acted upon by external forces. For instance, it may be desirable to maintain an angle of a beam of sunlight reflected by the heliostat to within +/−1 milliradian. Substantial wind forces on a planar object, such as a heliostat, may apply forces and torques which tend to knock the beam off-target. Heliostats, however, may require a stable operational platform and/or structure even when acted-upon by external forces, especially wind. Thus, a drive-mechanism for solar energy systems such as heliostats must produce a slow, precise, high-torque rotation. These requirements are often met by expensive multi-stage gearboxes with high reduction ratios, large torsional stiffness, and minimal backlash. Such gearboxes are notoriously expensive.

In some instances, a solar energy system may include an error-based feedback control system that compensates for steady-state loads (i.e., loads that are in a frequency domain of the control system). Thus, disturbances with the steady-state frequency may be compensated for by the control system. However, disturbances outside of the steady-state frequency range (e.g., wind loads and other dynamic loads) may increase “Sun-spillage” power losses.

### SUMMARY

In one general embodiment, a solar energy system includes a support member configured to be secured to a substantially fixed location; a solar energy member mounted to the support member and including a surface operable to track in response to movement of the Sun; an actuator assembly coupled to the solar energy member and configured to periodically apply a torque at a first frequency to move the solar energy member in response to movement of the Sun; and a damper assembly including a spool, where the damper assembly is configured to reactively release and retract a cable about the spool in response to changes in the torque at the first frequency, and maintain the cable at a substantially fixed length released from the spool in response to a torque at a second frequency greater than the first frequency that is intermittently received by the solar energy member, where the cable is coupled to the solar energy member.

In another general embodiment, a heliostat control assembly includes a support member configured to be secured to a substantially fixed location; a heliostat mirror mounted to the support member and including a reflective surface operable to face toward the Sun and reflect solar energy towards a solar energy receiver; an actuator assembly configured to periodically apply a substantially static load to move the heliostat mirror in accordance with movement of the Sun; and a damper assembly. The damper assembly includes a spool with a shaft configured to rotate to reactively release and retract a cable about the spool in response to changes in the substantially static load, and to maintain the cable at a substantially fixed length released from the spool in response to a dynamic load intermittently received by the heliostat mirror, where the cable is coupled to the heliostat mirror. The damper assembly also includes a viscous damper coupled to the shaft of the spool, and configured to resist rotary movement of the shaft to maintain the cable at the substantially fixed length released from the spool in response to the dynamic load intermittently received by the solar energy member. The damper assembly also includes a cable tensioning assembly coupled to the shaft and configured to apply a substantially constant torque on the shaft urging retraction of the cable around the spool; and a housing configured to sealingly enclose at least a portion of the damper assembly.

In another general embodiment, a method for controlling a solar energy system including a solar energy member, a vertical support post, and a damper assembly, includes: determining, with a controller, to move a solar energy member from a first position to a second position different than the first position; operating an actuator assembly to apply a substantially static torque to the solar energy member to move the solar energy member to the second position; in response to the substantially static torque, reactively releasing or retracting a portion of a cable about a spool of the damper assembly during movement of the solar energy member to the second position, where the cable is coupled to the solar energy member; and in response to a dynamic torque on the solar energy system, resisting rotational movement of the spool by a viscous damper of the damper assembly to substantially prevent release of the cable from the spool.

In one or more specific aspects of one or more general embodiments, the cable may include a first end coupled to the solar energy member; and a second end opposite the first end that is coupled to the spool of the damper assembly.

In one or more specific aspects of one or more general embodiments, the damper assembly may be supported by a terranean surface.

In one or more specific aspects of one or more general embodiments, the support member may be a first support member and the solar energy member may be a first solar energy member, and the damper assembly may be detachably secured to at least one of: a second support member; or a second solar energy member.

In one or more specific aspects of one or more general embodiments, the cable may include a first end coupled to a substantially fixed structure; and a second end opposite the first end that is coupled to the spool of the damper assembly, where the damper assembly is coupled to the solar energy member.

In one or more specific aspects of one or more general embodiments, the substantially fixed structure may include at least one of: a terranean surface; and a portion of a second solar energy system distinct from the solar energy system.

In one or more specific aspects of one or more general embodiments, the surface may include one of: a reflective surface configured to reflect rays from the Sun toward a solar energy receiver; a solar panel including a plurality of PV cells; or a reflective or refractive optical system configured to focus rays from the Sun onto a PV cell.

In one or more specific aspects of one or more general embodiments, the damper assembly may further include: a viscous damper coupled to a shaft of the spool, the viscous damper configured to resist rotary movement of the shaft to maintain the cable at the substantially fixed length released from the spool in response to the torque at the second frequency intermittently received by the solar energy member; and a cable tensioning assembly coupled to the shaft and configured to apply a substantially constant torque on the shaft, urging retraction of the cable around the spool.

In one or more specific aspects of one or more general embodiments, the cable tensioning assembly may include at least one of: a torsion spring configured to apply the substantially constant torque on the shaft; and an actuator configured to apply the substantially constant torque on the shaft.

In one or more specific aspects of one or more general embodiments, the actuator may be a stepper motor.

In one or more specific aspects of one or more general embodiments, the viscous damper may include a fluid disposed between a first surface coupled to the damper assembly and a second surface coupled to the shaft, such that a torque resisting rotational movement of the shaft is created based on a viscous force acting between the first and second surfaces due to the fluid.

In one or more specific aspects of one or more general embodiments, the viscous damper may include one of: a viscous damper having a paddlewheel entrained in fluid; or a viscous damper having a paddlewheel and at least one orifice, wherein rotary movement of the paddlewheel forces the fluid through the orifice.

In one or more specific aspects of one or more general embodiments, a damping coefficient of the viscous damper may have a value within at least one of the following ranges: between approximately 1,000 and approximately 50,000 Newton-seconds/meter; and between approximately 50,000 and approximately 200,000 Newton-seconds/meter.

In one or more specific aspects of one or more general embodiments, the fluid may be a silicone oil.

In one or more specific aspects of one or more general embodiments, a viscosity of the fluid may have a value within at least one of the following ranges: between approximately 10,000 and approximately 200,000 centiPoise; between approximately 200,000 and approximately 5,000,000 centiPoise; and between approximately 5,000,000 and 50,000,000 centiPoise.

In one or more specific aspects of one or more general embodiments, the resisting torque may be linearly proportional to a rotational speed of the shaft of the spool.

In one or more specific aspects of one or more general embodiments, the resisting torque may be linearly proportional to the rotational speed of the shaft of the spool according to the equation

τ₁=τ₂*ω₁/ω₂,

where τ₁ is the torque resisting rotational movement of the shaft; τ₂ is the torque at the first frequency; ω₁ is a rotational speed of the shaft due to the toque at the second frequency; and ω₂ is a rotational speed of the shaft due to the torque at the first frequency.

In one or more specific aspects of one or more general embodiments, the first frequency may be approximately 3.6*10⁻⁵ radians per second. The second frequency may be between approximately 0.5 Hz and 5 Hz.

One or more specific aspects of one or more general embodiments may further include a controller communicably coupled to the actuator assembly, the controller configured to drive the actuator assembly based on a position of the Sun relative to the surface of the solar energy member.

In one or more specific aspects of one or more general embodiments, the damper assembly may be supported by a terranean surface and the cable may include: a first end coupled to the heliostat mirror; and a second end opposite the first end that is coupled to the spool of the damper assembly.

In one or more specific aspects of one or more general embodiments, the housing may be detachably coupled to the terranean surface.

In one or more specific aspects of one or more general embodiments, the vertical support member may be a first vertical support member and the heliostat mirror may be a first heliostat mirror, and the damper assembly may be detachably secured to at least one of a second vertical support member or a second heliostat mirror, and the cable may be secured at a first end to a terranean surface and is secured at a second end opposite the first end to the spool of the damper assembly.

In one or more specific aspects of one or more general embodiments, the cable tensioning assembly may include at least one of: a torsion spring configured to apply the substantially constant torque on the shaft; and an actuator configured to apply the substantially constant torque on the shaft.

In one or more specific aspects of one or more general embodiments, the actuator may be the actuator assembly, and the actuator assembly may be configured to rotate the spool based on the substantially static load to reactively release and retract the cable about the spool.

In one or more specific aspects of one or more general embodiments, rotation of the spool based on the steady state load may move the heliostat mirror about at least one of: a first axis to adjust an azimuth position of the heliostat mirror; or a second axis to adjust an elevation position of the heliostat mirror.

In one or more specific aspects of one or more general embodiments, the viscous damper may include a fluid disposed between a first surface coupled to the damper assembly and a second surface coupled to the shaft, such that a torque resisting rotational movement of the shaft is created based on a viscous force acting between the first and second surfaces due to the fluid.

In one or more specific aspects of one or more general embodiments, a controller communicably coupled to the actuator assembly may also be included, where the controller is configured to drive the actuator assembly based on a position of the Sun relative to the reflective surface of the heliostat mirror.

In one or more specific aspects of one or more general embodiments, the dynamic load may include a wind load on at least a portion of the heliostat mirror.

One or more specific aspects of one or more general embodiments may also include: applying a substantially constant torque on the shaft by a cable tensioning assembly; urging retraction of the cable around the spool based on the substantially constant torque.

In one or more specific aspects of one or more general embodiments, resisting rotational movement of the spool by a viscous damper of the damper assembly may include generating a torque that resists rotational movement of the shaft based on a viscous force acting between a first surface and a second surface due to a fluid between the first and second surfaces, the first surface coupled to the damper assembly and the second surface coupled to the shaft.

In one or more specific aspects of one or more general embodiments, generating a torque that resists rotational movement of the shaft may include generating a first torque proportional to a first rotational speed of the shaft of the spool caused by the substantially static torque to move the solar energy member to the second position.

In one or more specific aspects of one or more general embodiments, generating a torque that resists rotational movement of the shaft may include generating a second torque proportional to a second rotational speed of the shaft of the spool caused by the dynamic torque on the solar energy system.

In one or more specific aspects of one or more general embodiments, the second torque may be approximately equal to the first rotational torque times a ratio of the second rotational speed to the first rotational speed.

In one or more specific aspects of one or more general embodiments, determining to move the solar energy member to a second position different than the first position may be based on a time of day, and the aspect may also include, in response to determining to move the solar energy member, automatically transmitting a signal to the actuator assembly to move the solar energy member to the second position.

Various implementations of a solar energy system including a damper assembly according to the present disclosure may include one or more of the following features and/or advantages. For example, system costs associated with system structure, such as mounting members, foundations, and drive mechanisms, may be substantially reduced, because dynamic loads and/or disturbances may be accounted for by the damper assembly rather than system structure or the drive mechanism. Further, system structure may be less rigid and, therefore, more “bendable” by being sized to primarily handle a steady-state load. For instance, certain system structure, such as a supporting members and articulation, may be substantially reduced in cost. The system including the damper assembly may have reduced power requirements due to a downsize in a drive assembly utilized to control a solar energy member of the system. As another example, the system including the damper assembly may maintain a solar energy member (e.g., a heliostat mirror or PV panel) at a substantially on-target position under both steady-state and dynamic loading. In addition, the system may utilize a rotary viscous damper to efficiently resist undesirable movement of a solar energy member due to a dynamic load using little to no power from the control system.

These general and specific aspects may be implemented using a device, system or method, or any combinations of devices, systems, or methods. The details of one or more implementations are set forth in the accompanying drawings and the description below. Other features, objects, and advantages will be apparent from the description and drawings, and from the claims.

### DESCRIPTION OF DRAWINGS

FIG. 1 illustrates an example embodiment of a solar energy system including one or more damper assemblies;

FIG. 2 illustrates another example embodiment of a solar energy system including one or more damper assemblies;

FIGS. 3A-3B illustrate example embodiments of a damper assembly;

FIGS. 4A-4B illustrate example embodiments of a solar energy system including one or more damper assemblies;

FIG. 5 illustrates an example method for controlling movement of a solar energy system; and

FIG. 6 illustrates another example method for controlling movement of a solar energy system.

### DETAILED DESCRIPTION

In some general embodiments, a solar energy system includes a solar energy member, such as a heliostat mirror or PV panel, which is mounted to a substantially vertical support member. One or more actuator assemblies, such as electric motors, are coupled to the solar energy member to facilitate steady-state movement of the solar energy member to track a location of the Sun. The actuator assemblies may further account for other steady-state loads on the solar energy system, such as steady wind loads, and maintain a proper position (e.g., pointing angle) of the solar energy member relative to the Sun. Periodically, the solar energy system may experience one or more transient, or dynamic loads, such as, for example, due to wind gusts. The solar energy system may include one or more damper assemblies to substantially diminish the impact of the transient loads. The damper assembly can include a damper coupled to a spool around which a cable coupled to the solar energy member may be reactively retracted and released. During the transient loads, the damper may apply a torque on the spool resisting release of the cable from the spool in proportion to the frequency of the transient load. The damper assembly may also include a tensioning assembly that urges retraction of the cable about the spool to keep the cable relatively taut.

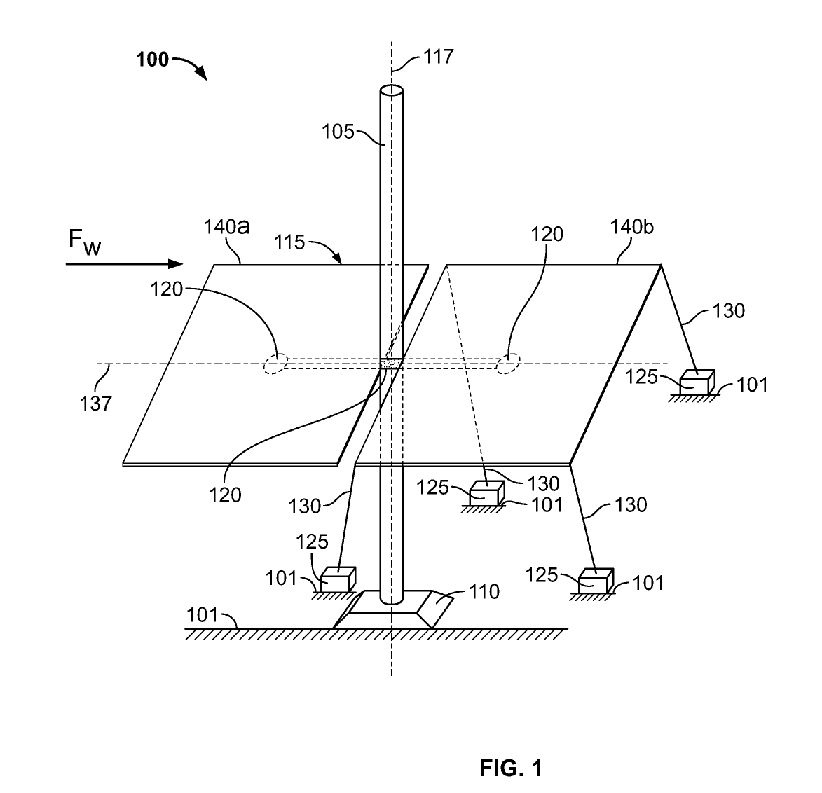

FIG. 1 illustrates an example embodiment of a solar energy system 100 including one or more damper assemblies 125. Solar energy system 100, as illustrated, may collect or reflect solar energy from a remote source (e.g., the Sun or other solar energy source) while rotatably tracking the source under varying environmental conditions. For example, in some embodiments, the solar energy system 100 may be a heliostat that tracks (e.g., rotates along an azimuth and/or pivots through an elevation) the Sun in order to receive and reflect solar energy from the Sun to a solar energy collector located remote from the heliostat. In some instances, the solar energy system 100 may be one of many systems 100 installed within a field or array that operate in concert to collect and/or reflect solar energy provided by the remote source.

In some instances, the solar energy system 100 may stably operate through a variety of environmental conditions, such as wind, rain, snow, hail, and other conditions. As illustrated, for example, the solar energy system 100 may be subject to a wind force (F_{w}) acting on one or more components of the system 100. The illustrated solar energy system 100 includes a support member 105, a solar energy member 115, and one or more damper assemblies 125 coupled to the solar energy member 115 by cables 130. As illustrated, the solar energy system 100 is secured to or supported by a terranean surface 101.

The support member 105, as illustrated, is substantially vertical in orientation and mounted orthogonal to the terranean surface 101 in a footer 110. The support member 105, in some embodiments, may be a wooden post, such as a cylindrical wooden post treated for exposure to varying environmental conditions (e.g., moisture, heat, and otherwise). Alternatively, the support member 105 may be any suitable material, such as stainless steel, painted ferrous steel, formed concrete, aluminum tubing, or otherwise, that may be secured in a substantially vertical position and support the solar energy member 115, with or without a footer 110.

The illustrated support member 105 is secured and/or attached to the footer 110 at a proximal end of the member 105. In some embodiments, the footer 110 may be a concrete foundation installed to a particular depth below the terranean surface 101, thereby forming a cantilevered beam with the support member 105.

Alternatively, the footer 110 may be supported by the terranean surface 101 without being installed or anchored below the surface 101. The footer 110 may be a structure that can support the member 105 in a substantially vertical position under the weight of the solar energy member 115 (both static weight and dynamic weight during movement of the solar energy member 115). For example, the footer 110 can be a block or mass of concrete or other material (e.g., glass reinforced plastic) that includes an aperture or other recess for installation of the support member 105 therein. Further, in some embodiments, the footer 110 may not be installed to support the member 105 and instead, the support member 105 may be inserted into a post hole formed in the terranean surface 101. In some instances, a footer 110 that is supported by the surface 101 or installation of the support member 105 without the footer 110 may be significantly more efficient (e.g., in relative costs, installation time, and otherwise) as compared to a foundational structure formed beneath the terranean surface 101.

As illustrated, the footer 110 may not need to resist any overturning moments in the support member 105, in contrast to, for example, a foundational structure formed beneath the terranean surface 101 for anchoring the support member 105. For instance, the footer 110 may only need to resist and/or substantially prevent lateral “skidding” of the footer 110 and support member 105 across the terranean surface 101. Further, the footer 110 may prevent or substantially prevent the support member 105 from sinking beneath the terranean surface 101.

Changes in azimuth of the solar energy member 115 refers to rotation of the solar energy member 115 about a vertical axis, i.e., rotation about an azimuthal axis 117. Changes in elevation of the solar energy member 115 refers to changes in the angle between the direction the solar energy member 115 is pointing and a local horizontal plane, i.e., changes in the up-down angle. As shown in FIG. 1, rotation of the solar energy member 115 in the direction about an elevational axis 137 changes the elevation of the solar energy member 115. The solar energy member 115 is mounted to the support member 105 such that rotation about the azimuthal axis 117 (in this implementation, coincident with a centerline of the support member 105) and rotation (i.e., pivotal movement) about the elevational axis 137 within desired ranges to account for tracking the Sun throughout the course of day and throughout the days of a year are permitted without interference by the support member 105 or the cables 130. In the illustrated embodiment, the solar energy member 115 may be a heliostat mirror, which receives and reflects solar energy incident on a surface of the member 115 towards a remote location, such as a solar energy receiver. Alternatively, however, the solar energy member 115 may be another solar energy device, such as a PV panel, or a reflective or refractive optic that focuses solar energy on a local or integrated PV cell (e.g., a concentrating PV system). In any event, the solar energy member 115, can be substantially planar or curved and includes at least one surface that receives and reflects (i.e., a heliostat mirror), refracts (e.g., a glass or polymer focusing lens), or receives and absorbs (i.e., a PV) solar energy.

In the illustrated embodiment, the solar energy member 115 is split into a first portion 140a and a second portion 140b, with the support member 105 extending vertically (e.g., substantially or otherwise) between the two portions 140a and 140b. In some embodiments, the first and second portions 140a and 140b may be substantially equal in surface area. Alternatively, the first and second portions 140a and 140b may differ in size, depending on, for example, the solar energy application. In some embodiments, the first portion 140a and the second portion 140b are joined or integral to each other and include an elongated opening in between the two portions through which the support member 105 passes, to allow for changes in azimuth and elevation of the solar energy member 115 (i.e., rotation about the azimuthal axis 117 and elevational axis 137). As illustrated, the first and second portions 140a and 140b are mounted near a position of the support member 105 that is between the ends of the member 105.

As illustrated, the solar energy member 115 may be coupled to the support member 105 through one or more actuator assemblies 120. Generally, each actuator assembly 120 facilitates rotational movement of all or part of the solar energy member 115 about the azimuthal axis 117 and/or the elevational axis 137. For example, as illustrated, each portion 140a and 140b of the solar energy member 115 may be coupled to the support member 105 through an actuator assembly 120 that facilitates rotational movement of the particular portion of the solar energy member 115 about the elevational axis 137. Further, as illustrated, both portions 140a and 140b of the solar energy member 115 may be coupled to the support member 105 through an actuator assembly 120 to facilitate rotational movement of the solar energy member 115 about the azimuthal axis 117.

Each actuator assembly 120 may be a motorized actuator, such as, for example, an electric motor, that operates to move the solar energy member 115 in order to, for instance, track the movement of the Sun across the daytime sky. For example, in some embodiments, one or more actuator assemblies 120 may operate to apply a substantially constant torque to the solar energy member 115 in order to gradually move the solar energy member 115 to track the Sun. This constant, or steady-state, torque applied by the one or more actuator assemblies 120 may cause the solar energy member 115 to rotate at a rate expressed by the following equation:

ω=0.5 rotations/day=1π_{rad}/86400 sec ≈3.6*10⁻⁵ radians/sec,

where ω is the angular speed of the solar energy member 115 as it moves to track the movement of the Sun. Thus, this steady-state torque may facilitate a relatively slow, but constant angular rotation of the solar energy member 115, which can be translated into motions about the azimuthal axis 117 and elevation axes 137. In some embodiments, the torque may vary but stay within a predetermined bandwidth. For example, torque may vary based on a position of the solar energy member 115 due to, for example, changes in weight and cable angles (e.g., angles of connections of the cables 130). Further, the angular speed of the solar energy member 115 may vary during the day depending on, for instance, the axes positions, location on the terranean surface, and time of year.

As illustrated, several damper assemblies 125 are supported by the terranean surface 101 and coupled to the solar energy member 115, and more particularly the portion 140b of the solar energy member 115, through the cables 130. Although FIG. 1 illustrates four damper assemblies 125 coupled to corners of the portion 140b of the solar energy member 115, more or fewer damper assemblies 125 may be used. Further, the damper assemblies 125 may be coupled to the portion 140b of the solar energy member 115 (or other parts of the solar energy member 115) at locations other than the corners.

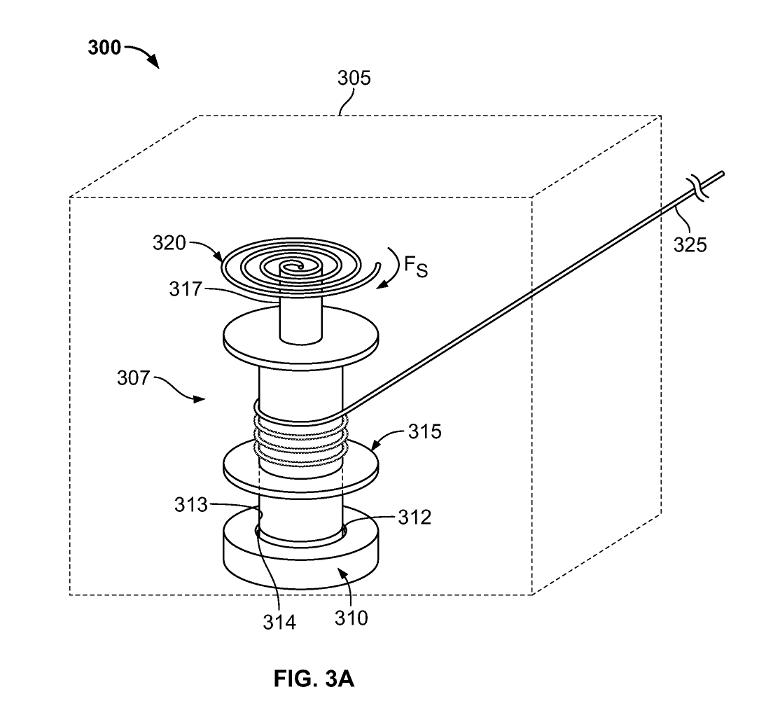

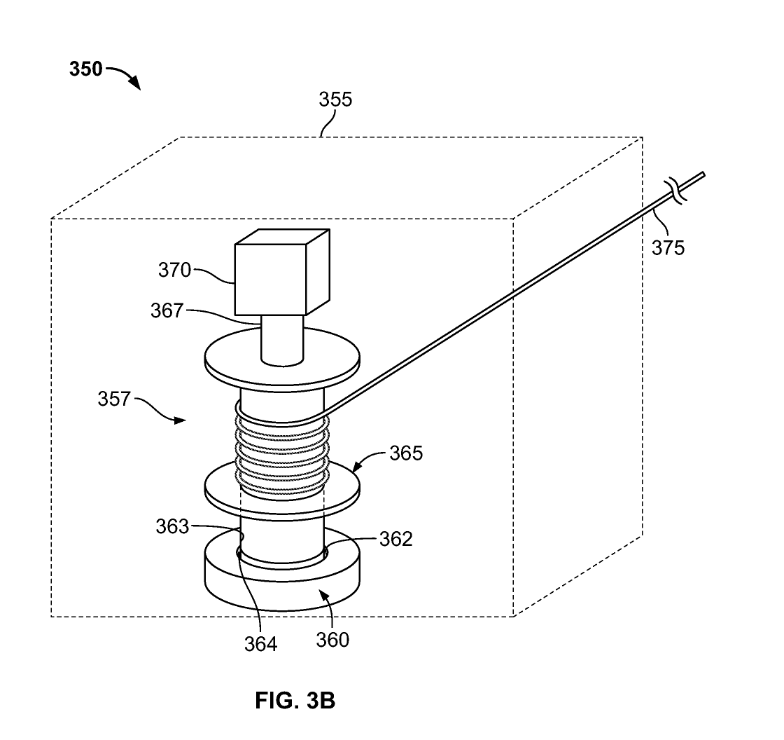

At a high level, each damper assembly 125 (described in more detail with reference to FIGS. 3A-3B) may be a dynamic restraint on the solar energy member 115, providing substantial damping resistance to motion of the solar energy member 115 caused by a dynamic load. In addition, each damper assembly 125 may optionally provide a tensioning mechanism to compensate for varying line lengths of the cables 130 as the solar energy member 115 moves about the azimuthal axis 117 and/or elevational axis 137. For instance, in one example operation, as the portion 140b of the solar energy member 115 rotates about the elevational axis 137, two of the illustrated damper assemblies 125 coupled to top corners of the portion 140b may operate to reel in corresponding cables 130, while the other two damper assemblies 125 coupled to bottom corners of the portion 140a may operate to release additional cable 130 (as described more fully below). The release of length of cables 130 by the damper assemblies 125 may be in response to the steady-state torque applied by one or more actuator assemblies 120 to the solar energy member 115 while the damper assemblies 125 restrict the release of length of cables 130 due to a dynamic load (e.g., a wind load or otherwise) on the solar energy member 115 (or other component of the system 100). For instance, each damper assembly 125 may include a viscous damper (e.g., a dashpot) that restricts release of the length of cable 130 in proportion to the dynamic load placed on the solar energy member 115.

Further, although not illustrated, additional or fewer damper assemblies 125 may be coupled to the portion 140a of the solar energy member 115. For example, while four damper assemblies 125 may be used for optimal positioning (e.g., restricting movement of the solar energy member 115 due to dynamic loads and/or actuating movement of the solar energy member 115 in the absence of actuator assemblies 120) about two axes, i.e., the azimuthal and elevational axes, fewer damper assemblies 125 may be utilized as well. For instance, three damper assemblies 125 may be coupled to the portion 140b of the solar energy member 115 while still providing optimal positioning of the solar energy member 115 about two axes.

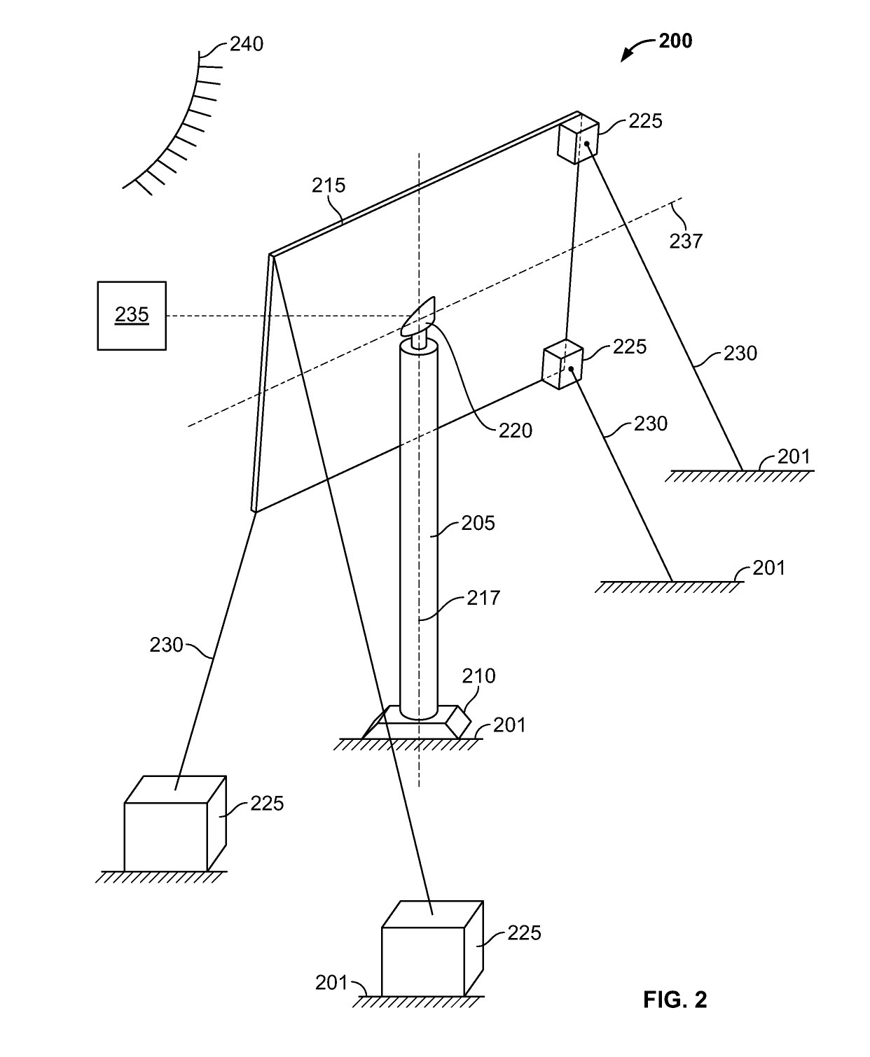

FIG. 2 illustrates another example embodiment of a solar energy system 200 including one or more damper assemblies 225. Solar energy system 200, as illustrated, may collect or reflect solar energy from a remote source (e.g., the Sun or other solar energy source) while rotatably tracking the source under varying environmental conditions similarly to solar energy system 100. For example, in some embodiments, the solar energy system 200 may be a heliostat that tracks (e.g., rotates along an azimuth and/or pivots through an elevation) the Sun in order to receive and reflect solar energy from the Sun to a solar energy collector located remote from the heliostat. In some instances, the solar energy system 200 may be one of many systems 100 installed within a field or array that operate in concert to collect and/or reflect solar energy provided by the remote source.

Solar energy system 200 includes a solar energy member 215 (e.g., a heliostat mirror or PV panel) mounted to a support member 205 through an actuator assembly 220. The support member 205 is a substantially vertical member supported by a terranean surface 201 through a footer 210. The support member 205, the footer 210, and the solar energy member 215 may be substantially similar to those components illustrated in FIG. 1. As illustrated in FIG. 2, however, the solar energy member 215 may be a single-piece member mounted to a top portion of the support member 205. Thus the actuator assembly 220 may be a single assembly or may include multiple assemblies that operate to rotate the solar energy member 220 about one or both of an azimuthal axis 217 and an elevational axis 237.

In the illustrated embodiment, a controller 235 is communicably coupled to the actuator assembly 220. The controller 235, generally, may be a microprocessor-based controller utilizing a combination of hardware and/or software to receive data and transmit commands through signals (e.g., wired, wireless, or a combination thereof) to the actuator assembly 220 to control the assembly 220. For example, the controller 235 may be communicably coupled with the actuator assembly 220 and operably control the assembly 220 to rotate the solar energy member 215 about the azimuthal axis 217. The controller 235 may receive and/or measure various data, such as a position of the Sun 240, and other data (e.g., time of day, wind speed, solar receiver location, error signals or otherwise) and algorithmically determine an optimal azimuthal position or direction of motion of the solar energy member 215. The controller 235 may then transmit signals to the actuator assembly 220 to operate the assembly 220 to rotate the solar energy member 215 to the optimal azimuthal position or at a desired angular rate.

In other alternative embodiments of system 200, there may be additional controllers. For example, there may be a one-to-one ratio of controllers 235 to actuator assemblies 220. Or, alternatively, there may be a single controller 235 for multiple actuator assemblies 220. Further, the controller 235 may be located at the system 200, such as mounted to a component of the system 200. Alternatively, the controller 235 may be remotely-located from the system 200. Further, the controller 235 (or multiple controllers 235) may be communicably coupled to one or more of the damper assemblies 225 to control operation of the assemblies 225 according to, for example, a measured wind load, Sun position, time of day, solar receiver position, and otherwise.

As illustrated, certain damper assemblies 225 are mounted to corners of the solar energy member 215 and secured to the terranean surface 201 through cables 230. Other damper assemblies 225 could be mounted to the terranean surface 201 (e.g., secured by stakes or other apparatus or just supported by the surface 201) and coupled to the solar energy member 215 by cables 230. Alternatively, some embodiments of the system 200 may have each of the damper assemblies 225 mounted on the terranean surface 201. In alternative embodiments, each of the damper assemblies 225 may be mounted to the solar energy member 215 and coupled to the terranean surface 201 by cables 230. In some embodiments more or fewer damper assemblies are used and/or the damper assemblies are located at different positions relative to the solar energy member 215 than what is shown.

Each damper assembly 225 may be substantially similar to the damper assemblies 125 described with reference to FIG. 1. For example, each damper assembly 225 may provide a dynamic restraint on the solar energy member 215, providing substantial damping resistance to motion of the solar energy member 215 caused by a dynamic load. In addition, each damper assembly 225 may optionally provide a tensioning mechanism to compensate for varying line lengths of the cables 230 as the solar energy member 215 moves about the azimuthal axis 217 and/or elevational axis 237. The release of length of cables 230 by the damper assemblies 225 may be in response to the steady-state torque applied by the actuator assembly 220 to the solar energy member 215 while the damper assemblies 225 restrict the release of length of cables 230 due to a dynamic load (e.g., a wind load or otherwise) on the solar energy member 215 (or other component of the system 200). For instance, each damper assembly 225 may include a viscous damper that restricts release of the length of cable 230 in proportion to the dynamic load placed on the solar energy member 215.

In some embodiments, a tensioning mechanism of the damper assembly 225 (or other damper assembly within the scope of the present disclosure) may not be integrated within a housing of the damper assembly 225. For example, the tensioning assembly could be coupled to a cable, such as the cable 230, but external to the housing of the damper assembly 225.

FIGS. 3A-3B illustrate example embodiments of a damper assembly that may be used in the solar energy systems 100 and 200 as, for example, one or more of the damper assemblies 125 and 225. Turning to FIG. 3A in particular, a damper assembly 300 is illustrated including a housing 305 enclosing at least a portion of a damper sub-assembly 307. The illustrated damper sub-assembly 307 includes a damper (e.g., a viscous damper) 310, a spool 315, and a tensioning assembly 320. The damper assembly 300 also includes a cable 325 coupled to the spool 315 that may be retracted to and released from the spool 315 based on, for example a steady-state load and/or a dynamic load exerted on a solar energy member. For example, in some embodiments, the cable 325 may be secured to a solar energy member, such as solar energy member 115 or solar energy member 215. Alternatively, the cable 325 may be secured to a terranean surface as shown in FIG. 2 or other structure, such as another solar energy system.

The housing 305, in some embodiments, may be made of a heavy material to keep the damper assembly 300 mounted to a terranean surface at a fixed location. For example, the housing 305 can be made of concrete or cinderblock. Alternatively, or additionally, the housing 305 may be secured to the terranean surface with stakes, helical screws, or other mechanical fasteners. In any event, in some embodiments, the housing 305 may not be subject to any overturning moment, but may only be secured with respect to any tension forces acting upon the cable 325.

The damper 310, as illustrated, includes an enclosure filled or partially filled with a fluid 314 (e.g., water, oil, a non-Newtonian fluid such as corn starch, or other fluid) that is disposed between and in contact with an interior surface 312 of the damper 310 and an exterior surface 313 of the spool 315. For example, the fluid 314 may be in contact with the interior surface 312 of the damper 310 and a shaft 317 of the spool 315 that is disposed through a center aperture of the spool 315. In any event, the fluid 314 is disposed within the damper 310 and the spool 315 is coupled to the damper 310 such that a torque generated by a frictional fluid force acts on the spool 315 to, for example, restrict rotational movement of the spool 315.

Although certain types of viscous dampers are illustrated herein, other types of viscous dampers are within the scope of the present disclosure. For example, while rotary viscous dampers may be utilized in one or more damper assemblies, a viscous damper having a friction of fluid between rotating plates may be used. Further, a viscous damper having a paddlewheel entrained in fluid may be used. In addition, a viscous damper having a paddlewheel with constricted orifice(s) through which fluid is forced may be used, as well as other types of viscous dampers.

Moreover, in some embodiments, the viscous dampers used in the damper assemblies described herein may be constructed of more efficient (e.g., less costly) material (e.g., chlorinated polyvinyl chloride). For example, the viscous dampers may dissipate a reduced amount of heat during operation as compared to other viscous dampers (e.g., automotive viscous dampers). In some embodiments, the reduced amount may be on the scale of 200 to 1.

In some embodiments, the damper 310 may be chosen according to one or more physical properties. For example, the damper 310 may be characterized by a damping coefficient (i.e., the coefficient, k, described below). Further, the damper 310 may be characterized by a viscosity of the fluid 314 (i.e., the coefficient, μ, described below). The damping coefficient of the damper 310, in some embodiments, is within the range of approximately 1,000 and approximately 50,000 Newton-seconds/meter. Alternatively, other ranges of the damping coefficient include between approximately 50,000 and approximately 200,000 Newton-seconds/meter. In addition, the viscosity of the fluid 314, which in some embodiments may be a silicon oil, is between at least one of the following ranges: approximately 10,000 and approximately 200,000 centiPoise; approximately 200,000 and approximately 5,000,000 centiPoise; and approximately 5,000,000 and 50,000,000 centiPoise.

In some embodiments, the damper 310 may apply a torque on the spool 315 to restrict (partially or completely) rotational movement of the spool 315 in relation to an angular speed of a solar energy member due to a dynamic load on the member, such as a wind load. For instance, as the dynamic load increases, the torque resistant to rotation of the spool 315 may also increase, effectively locking the spool 315 against rotational movement. Thus, the damper 310 may effectively prevent the spool 315 from releasing additional cable 325 in response to a dynamic load. As the additional length of cable 325 is prevented from being released, a solar energy member coupled to the cable 325, for example, may remain in a substantially static position even under a dynamic load, such as a wind load.

For example, a wind load, i.e., force on one or more components of a solar energy system, such as on the solar energy member, due to gusts of wind, may induce a torque on the solar energy member across a spectrum of frequencies. In some instances, a steady wind gust may be close to or approach 0.5 Hz, while large transient gusts may approach 5 Hz (or larger). While in some embodiments illustrated herein, a control system with an actuator assembly, may be able to compensate for steady wind loads of about 0.5 Hz, but transient and/or larger wind gusts may induce a torque on the solar energy member that is accounted for by the damper assembly 300. That is, while an actuator assembly may keep a solar energy member on target (e.g., aimed at a solar receiver at a particular angle based on the location of the receiver and position of the Sun) during steady wind loads, the damper assembly 300 may keep the solar energy member on target by restricting movement of the spool 315 to release cable 325 during transient and/or dynamic wind loads (e.g., wind loads at frequencies of between approximately 0.5 Hz and 5 Hz).

The torque generated by the damper 310 on the spool 315 to restrict and/or prevent release of the cable 325 may be described by the following equation:

τ_{wind}=k*μ*ω_{wind},

where τ_{wind} is the torque generated by the damper 310 on the shaft 317 of the spool 315 based on a dynamic load, k is a viscous damper constant, μ is a viscosity of the fluid 314, and ω_{wind} is the rotational speed of the shaft 317 caused by a transient and/or dynamic wind load in radians/second. In the example given above, ω_{wind} is between approximately 3.14 radians per second and 31.4 radians per second (i.e., 0.5 to 5 Hz).

As described above, a constant, or steady-state, torque applied by an actuator assembly may cause a solar energy member to rotate about an azimuthal axis at a frequency of approximately 3.6*10⁻⁵ radians per second in order to track the Sun across the daytime sky. The torque generated by the damper 310 on the spool 315 based on this rotational speed may be described by the following equation:

τ_{track}=k*μ*ω_{track},

where τ_{track} is the torque generated by the damper 310 on the shaft 317 of the spool 315 based on the steady-state load applied on the shaft 317 of the spool 315 by the actuator assembly, k is the viscous damper constant, μ is the viscosity of the fluid 314, and ω_{track} is the rotational speed of the shaft 317, which is approximately 3.6*10⁻⁵ radians per second. The ratio of τ_{wind} to τ_{track} may therefore be calculated as follows:

τ_{wind}/τ_{track}=k*μ*ω_{wind}/k*μ*ω_{track}=ω_{wind}/ω_{track}.

The torque generated by the damper 310 on the shaft 317 of the spool 315 based on a dynamic wind load may therefore be determined as a function of the torque generated by the damper 310 on the shaft 317 of the spool 315 based on the steady-state load applied on the shaft 317 of the spool 315 by the actuator assembly:

τ_{wind}=τ_{track}*ω_{wind}/ω_{track}.

Depending on the value of the rotational speed of the shaft 317 caused by a transient and/or dynamic wind load in radians/second (i.e., ω_{wind}), which can be between 3.14 and 31.4 radians per second, τ_{wind} may be between approximately 87 thousand times and 870 thousand times the value of τ_{track}. In other words, the ability to resist wind τ_{wind} is much greater than the resistance offered to tracking τ_{track}, thereby allowing the damper assembly 300 to prevent (all or partially) rotation of the spool 315 which would release cable 325 due to a dynamic load on, for example, a solar energy member, while allowing the damper 310 to allow rotation of the spool 315 to release cable 325 due to a steady-state load on the solar energy member.

In some embodiments, the above-described equations may describe, for example, an ideal solar energy system with a damper assembly. For example, the above-equations may describe a system utilizing an ideal (i.e., Newtonian) fluid with an ideal (e.g., no leaks) viscous damper. In some embodiments, however, one or more components of the solar energy system may not be ideal, such as the fluid and/or viscous damper. Thus, other, non-linear equations may also describe the system with the damper assembly. In any event, the relationship between τ_{wind} and τ_{track} (i.e., τ_{wind} may be much greater than τ_{track}) may be accurate regardless of the linearity (or non-linearity) of the solar energy system.

The damper sub-assembly 307 also includes the tensioning assembly 320 coupled to the shaft 317 of the spool 315. In this illustrated embodiment, the tensioning assembly 320 includes a torsion spring that applies a spring force, Fₛ, to the shaft 317 to urge (periodically or constantly) a rotational movement of the shaft 317 and thus spool 315 to retract the cable 325 about the spool 315. For example, the tensioning assembly 320 may function to ensure that any additional slack in the cable 325, such as slack between the spool 315 and a solar energy member or slack between the spool 325 and a terranean surface (or other structure) is removed from the cable 325.

Turning to FIG. 3B, a damper assembly 350 is illustrated, including a housing 355 and a damper sub-assembly 357. The illustrated damper sub-assembly 357 includes a damper 360 including an interior surface 362 and a fluid 364; a spool 365 including a shaft 367 and an exterior surface 363; a tensioning assembly 370; and a cable 375 coupled to the spool 365. In some embodiments of the damper assembly 350, the housing 355, the damper 360, the spool 365, and the cable 375 may be substantially similar to those components described above with respect to the damper assembly 300.

In the illustrated embodiment of the damper sub-assembly 357, the tensioning assembly 370 is an actuator, such as an electric motor (e.g., a stepper motor). In some aspects of the tensioning assembly 370, the assembly 370 may apply a rotational movement to the shaft 367 of the spool 365 based on slack detected in the cable 375. Further, although not illustrated, the tensioning assembly 370 may be coupled to the shaft 367 through a multiplication-gear in order to, for example, accommodate greater slack take-up length of the cable 375. In alternative embodiments of the damper assembly 350, the tensioning assembly 370 may be an actuator assembly (such as the actuator assembly 120 and/or actuator assembly 220), which may facilitate movement of a solar energy member about an azimuthal and/or elevational axis. For instance, the tensioning assembly 370 as an actuator assembly may operate to move the solar energy member in order to, for instance, track the movement of the Sun across the daytime sky.

Operationally, this may be accomplished by, for example, applying a steady-state torque to the spool 365 by the tensioning assembly 370 to release or retract the cable 375 that is coupled to the solar energy member. As the cable 375 is released or retracted, the solar energy member may be moved (e.g., rotated and/or pivoted) to track the movement of the Sun. As the tensioning assembly 370 applies a steady-state load with a low angular speed (e.g., on the order of 3.6*10⁻⁵ radians per second) to the shaft 367, the damper 360 allows rotation of the spool 365 (as described above) while still preventing (all or partially) rotation of the spool 365 due to a dynamic load (e.g., a wind load).

In some embodiments, a controller (not shown) may be communicably coupled to the tensioning assembly 370, such as the controller 235 shown in FIG. 2. A controller communicably coupled to the tensioning assembly 370, in some aspects, may operably control the assembly 370 to rotate the spool 365 to release or retract the cable 375. For example, the controller may receive and/or measure various data, such as a position of the Sun, and other data (e.g., time of day, wind speed, solar receiver location, or otherwise) and algorithmically determine an optimal azimuthal (and/or elevational) position of a solar energy member coupled to the cable 375. The controller may then transmit signals to the tensioning assembly 370 to operate the assembly 370 to rotate the spool 365. In some embodiments, a solar energy system may include a damper assembly 350 with a tensioning assembly 370 as described above and configured to adjust an azimuthal position of a solar energy member while also including a damper assembly 350 with a tensioning assembly 370 as described above and configured to adjust an elevational position of the solar energy member.

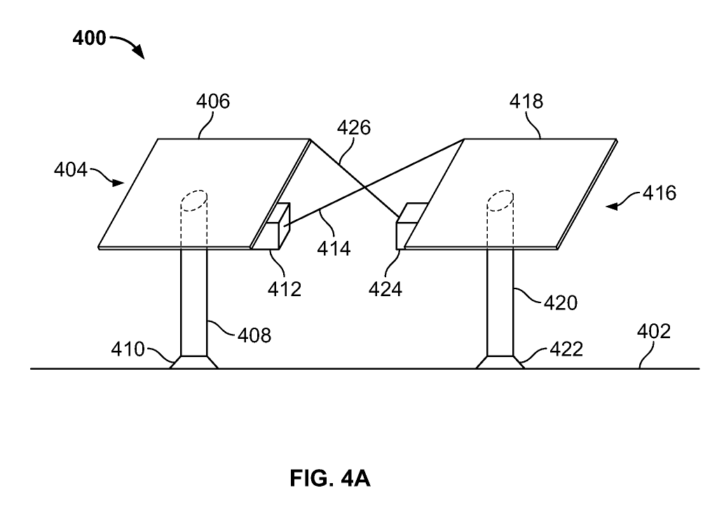

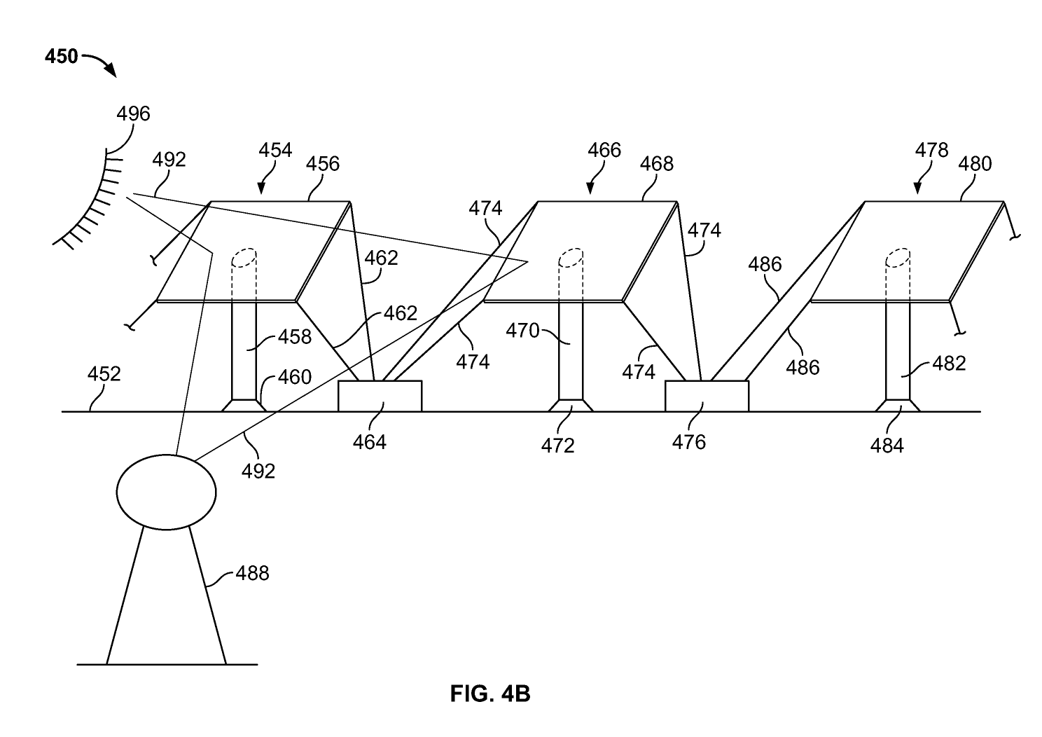

FIGS. 4A-4B illustrate example embodiments of solar energy arrays 400 and 450 including one or more damper assemblies. Solar energy arrays 400 and 450, as illustrated, show example configurations of multiple solar energy systems, i.e., within an array of solar energy systems, coupled together through one or more damper assemblies. Turning to FIG. 4A in particular, solar energy array 400 includes solar energy systems 404 and 416. Solar energy system 404 includes a solar energy member 406 mounted to a support member 408, which is coupled to a footer 410 supported by a terranean surface 402. Solar energy system 416 includes a solar energy member 418 mounted to a support member 420, which is coupled to a footer 422 supported by the terranean surface 402. As illustrated, solar energy system 404 includes a damper assembly 412 mounted to the solar energy member 406 with a cable 414 extending from the damper assembly 412 and coupled to the solar energy member 418 of the solar energy system 416. The solar energy system 416 includes a damper assembly 424 mounted to the solar energy member 418 with a cable 426 extending from the damper assembly 424 and coupled to the solar energy member 406 of the solar energy system 404.

In the illustrated embodiment of solar energy array 400, the damper assemblies 412 and 424 may operate as described above with respect to FIGS. 1, 2, and 3A-3B. For example, as solar energy member 418 is moved by a steady-state load (e.g., by an actuator assembly) to, for instance, track a movement of the Sun, cable 426 may be extended or retracted by the damper assembly 424 to account for the steady-state movement. Likewise, as solar energy member 406 is moved by a steady-state load (e.g., by an actuator assembly) to track a movement of the Sun, cable 414 may be extended or retracted by the damper assembly 412 to account for the steady-state movement. As a dynamic load (e.g., a wind load) acts upon one or both of the solar energy systems 404 and 416, the damper assemblies 412 and 424 may operate to resist release of the cables 414 and 426, respectively, as described above. Further, as solar energy member 406 is moved, for example, cable 426 may be automatically retracted into the damper assembly 424, such as by a tensioning assembly within the damper assembly 424, as described above. In some embodiments, cables 414 and 426 do not interfere with movement of the solar energy member 406, e.g., cable 414 does not act to pull and move the solar energy member 418.

Turning to FIG. 4B, the solar energy array 450 includes solar energy systems 454, 466, and 478, which, as illustrated, receive solar energy 492 from the Sun 496 and reflect the solar energy 492 towards a solar energy receiver 488. Thus, as illustrated, solar energy array 450 includes a plurality of heliostats (i.e., the solar energy systems 454, 466, and 478) that receive and reflect solar energy towards a solar energy receiver. Of course, in other embodiments of solar energy array 450, the solar energy systems 454, 466, and 478 may be PV systems which receive the solar energy 492 and convert it to electricity without the need for the solar energy receiver 488. Further, the solar energy array 450 may include more (or fewer) solar energy systems than those illustrated.

Solar energy system 454 includes a solar energy member 456 mounted to a support member 458, which is coupled to a footer 460 supported by a terranean surface 452. Solar energy system 466 includes a solar energy member 468 mounted to a support member 470, which is coupled to a footer 472 supported by the terranean surface 452. Solar energy system 478 includes a solar energy member 480 mounted to a support member 482, which is coupled to a footer 484 supported by the terranean surface 452. Each of the aforementioned similarly named components may be substantially similar in structure and operation and, in some embodiments, may be substantially similar to similarly-named components described above with respect to FIGS. 1, 2, and 3A-3B.

As illustrated, solar energy array 450 also includes damper assemblies 464 and 476. Damper assembly 464 includes cables 462 extending and secured to the solar energy member 456. Damper assembly 464 also includes cables 474 extending and secured to the solar energy member 468. Thus, damper assembly 464 may include a plurality of damper sub-assemblies within a common housing, such as a plurality of damper assemblies 307 described with reference to FIG. 3A. For example, the housing of damper assembly 464 may enclose at least a portion of several damper sub-assembly components, such as multiple (e.g., four) dampers, spools, and tensioning assemblies (e.g., springs, actuator assemblies, or otherwise). Of course, damper assembly 464 may include other components, such as controllers or otherwise.

As further illustrated, damper assembly 476 also includes cables 474 extending and secured to the solar energy member 468. Damper assembly 464 also includes cables 486 extending and secured to the solar energy member 480. As with damper assembly 464, damper assembly 476 may include a plurality of damper sub-assemblies within a common housing, such as a plurality of damper assemblies 307 described with reference to FIG. 3A.

Although illustrated as separately mounted on the terranean surface 452, the damper assemblies 464 and 476 may be mounted in other locations as well. For example, one or both of the damper assemblies 464 and 476 (as well as other damper assemblies of solar energy array 450) may be mounted on one of the solar energy systems 454, 466, or 478. For instance, damper assembly 464 may be integrated with the support member 458 or the footer 460 of solar energy system 454.

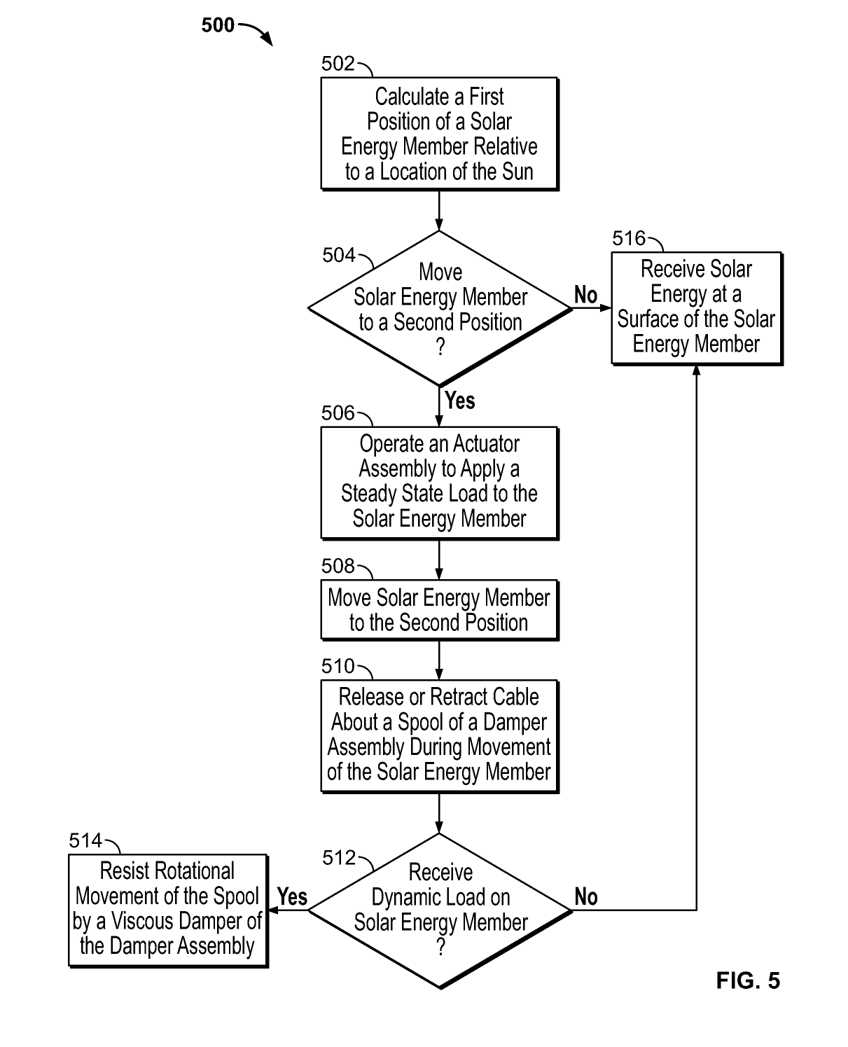

FIG. 5 illustrates an example method 500 for controlling movement of a solar energy system. In some embodiments, method 500 may be performed by all or part of a solar energy system, such as solar energy system 100, solar energy system 200, other solar energy systems described herein, or other solar energy systems in accordance with the present disclosure. Method 500 may begin at step 502, when a first position of a solar energy member of a solar energy system may be calculated relative to a location of the Sun. For example, a controller or other part of a solar energy system may calculate the first position based on time of day, solar energy intensity incident on the solar energy member, as well as other data. Next, a determination is made whether to move the solar energy member to a second position at step 504. For example, in some embodiments, the solar energy member may be constantly moving (e.g., rotating) about an azimuthal axis at a slow angular speed to track the Sun. Alternatively, determinations may be periodically made, e.g., by the controller, to move the solar energy member.

If a determination is made not to move the solar energy member, then the solar energy member continues to receive solar energy at a surface of the member at step 516. If a determination is made to move the solar energy member to the second position at step 504, then an actuator assembly is operated to apply a steady-state load to the solar energy member to, for example, rotate the solar energy member about one or more axes at step 506. The solar energy member is then moved to the second position at step 508. Next, at step 510, a cable is released or retracted about a spool of a damper assembly of the solar energy system during movement of the solar energy system. For instance, during steady-state movement, the cable coupled between the damper assembly and the solar energy member (or between a terranean surface and the damper assembly mounted on the solar energy system) may need to be released from the spool to accommodate the angular rotation of the solar energy member.

At step 512, the solar energy member may or may not receive a dynamic load. For example, the solar energy member (or other component of the solar energy system) may receive wind gusts that generate a dynamic and/or transient load on the solar energy member that can be much greater than the steady-state load. If no dynamic load is received, then the solar energy member continues to receive solar energy at the surface of the solar energy member at step 516. If a dynamic load is received, then additional rotational movement of the solar energy member (e.g., about the azimuthal and/or elevational axes) is restricted by restriction of rotation of the spool to release additional cable length by a viscous damper of the damper assembly at step 514. For instance, the viscous damper may generate a torque on the spool restricting (partially or completely) rotation of the spool so that additional cable length is not released (as described above).

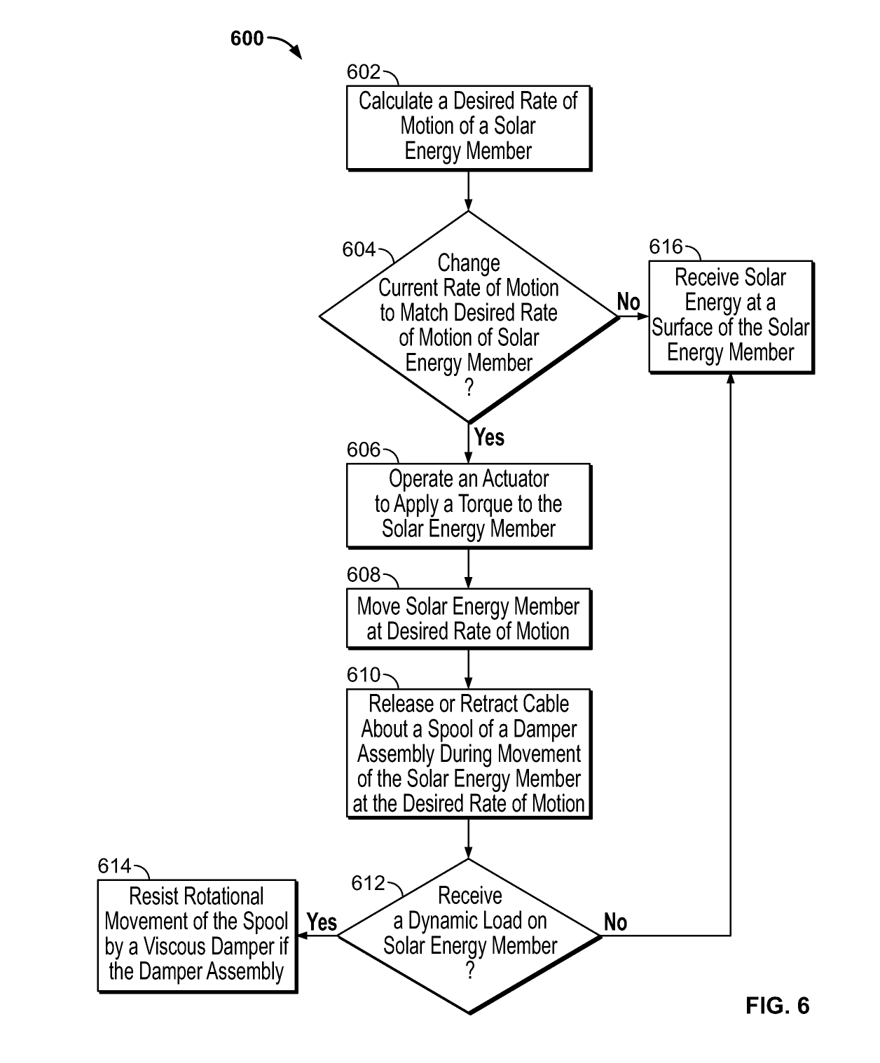

FIG. 6 illustrates an example method 600 for controlling movement of a solar energy system. In some embodiments, method 600 may be performed by all or part of a solar energy system, such as solar energy system 100, solar energy system 200, other solar energy systems described herein, or other solar energy systems in accordance with the present disclosure. Method 600 may begin at step 602, when a desired rate of motion (e.g., rotational or pivotal movement) of a solar energy member of a solar energy system may be calculated. For example, a controller or other part of a solar energy system may calculate the desired rate of motion based on time of day, solar energy intensity incident on the solar energy member, as well as other data. Next, a determination is made whether to change a current rate of motion of the solar energy member to match the desired rate of motion at step 604. For example, in some embodiments, the solar energy member may be constantly moving (e.g., rotating) about an azimuthal axis at a slow angular speed to track the Sun. The constant rate of motion may be different (e.g., slower) than the desired rate of motion. For instance, in some embodiments, the current rate of motion may be substantially zero.

If a determination is made not to change a current rate of motion of the solar energy member to match the desired rate of motion, then the solar energy member continues to receive solar energy at a surface of the member at step 616. If a determination is made to change a current rate of motion of the solar energy member to match the desired rate of motion at step 604, then an actuator assembly is operated to apply a torque to the solar energy member to, for example, rotate the solar energy member about one or more axes at the desired rate of motion at step 606. The solar energy member is then moved at the desired rate of motion at step 608. Next, at step 610, a cable is released or retracted about a spool of a damper assembly of the solar energy system during movement of the solar energy member at the desired rate of motion. For instance, during movement at the desired rate of motion, the cable coupled between the damper assembly and the solar energy member (or between a terranean surface and the damper assembly mounted on the solar energy system) may need to be released from the spool to accommodate the new angular rotation of the solar energy member.

At step 612, the solar energy member may or may not receive a dynamic load. For example, the solar energy member (or other component of the solar energy system) may receive wind gusts that generate a dynamic and/or transient load on the solar energy member that can be much greater than the steady-state load. If no dynamic load is received, then the solar energy member continues to receive solar energy at the surface of the solar energy member at step 616. If a dynamic load is received, then additional rotational movement of the solar energy member (e.g., about the azimuthal and/or elevational axes) is restricted by restriction of rotation of the spool to release additional cable length by a viscous damper of the damper assembly at step 614. For instance, the viscous damper may generate a torque on the spool restricting (partially or completely) rotation of the spool so that additional cable length is not released (as described above).

A number of implementations have been described. Nevertheless, it will be understood that various modifications may be made. For example, while some embodiments have been described and/or illustrated in terms of heliostats, other solar energy members, such as PV panels, may also be utilized in accordance with the present disclosure. Further, methods 500 and 600 may include less steps than those illustrated or more steps than those illustrated. In addition, the illustrated steps of methods 500 and 600 may be performed in the order illustrated, in different orders than that illustrated, or simultaneously. Accordingly, other implementations are within the scope of the following claims.

What is claimed is:

1. A solar energy system, comprising:
a support member configured to be secured to a substantially fixed location;
a solar energy member mounted to the support member and comprising a surface operable to track in response to movement of the Sun;
an actuator assembly coupled to the solar energy member and configured to periodically apply a torque at a first frequency to move the solar energy member in response to movement of the Sun; and
a damper assembly including a spool, the damper assembly configured to reactively release and retract a cable about the spool in response to changes in the torque at the first frequency, and maintain the cable at a substantially fixed length released from the spool in response to a torque at a second frequency greater than the first frequency that is intermittently received by the solar energy member, wherein the cable is coupled to the solar energy member.

2. The solar energy system of claim 1, wherein the cable comprises:
a first end coupled to the solar energy member; and
a second end opposite the first end that is coupled to the spool of the damper assembly.

3. The solar energy system of claim 2, wherein the damper assembly is supported by a terranean surface.

4. The solar energy system of claim 2, wherein the support member is a first support member and the solar energy member is a first solar energy member, and wherein the damper assembly is detachably secured to at least one of:
a second support member; or a second solar energy member.

5. The solar energy system of claim 1, wherein the cable comprises:
a first end coupled to a substantially fixed structure; and
a second end opposite the first end that is coupled to the spool of the damper assembly, wherein the damper assembly is coupled to the solar energy member.

6. The solar energy system of claim 5, the substantially fixed structure comprises at least one of:
a terranean surface; and
a portion of a second solar energy system distinct from the solar energy system.

7. The solar energy system of claim 1, wherein the surface comprises one of:
a reflective surface configured to reflect rays from the Sun toward a solar energy receiver;
a solar panel including a plurality of PV cells; or
a reflective or refractive optical system configured to focus rays from the Sun onto a PV cell.

8. The solar energy system of claim 1, wherein the damper assembly further comprises:
a viscous damper coupled to a shaft of the spool, the viscous damper configured to resist rotary movement of the shaft to maintain the cable at the substantially fixed length released from the spool in response to the torque at the second frequency intermittently received by the solar energy member; and
a cable tensioning assembly coupled to the shaft and configured to apply a substantially constant torque on the shaft, urging retraction of the cable around the spool.

9. The solar energy system of claim 8, wherein the cable tensioning assembly comprises at least one of:
a torsion spring configured to apply the substantially constant torque on the shaft; and
an actuator configured to apply the substantially constant torque on the shaft.

10. The solar energy system of claim 9, wherein the actuator is a stepper motor.

11. The solar energy system of claim 8, wherein the viscous damper comprises a fluid disposed between a first surface coupled to the damper assembly and a second surface coupled to the shaft, such that a torque resisting rotational movement of the shaft is created based on a viscous force acting between the first and second surfaces due to the fluid.

12. The solar energy system of claim 8, wherein the viscous damper comprises one of:
a viscous damper having a paddlewheel entrained in fluid; or
a viscous damper having a paddlewheel and at least one orifice, wherein rotary movement of the paddlewheel forces the fluid through the orifice.

13. The solar energy system of claim 11, wherein a damping coefficient of the viscous damper has a value within at least one of the following ranges:
between approximately 1,000 and approximately 50,000 Newton-seconds/meter; and
between approximately 50,000 and approximately 200,000 Newton-seconds/meter.

14. The solar energy system of claim 11, wherein the fluid is a silicone oil.

15. The solar energy system of claim 11, wherein a viscosity of the fluid has a value within at least one of the following ranges:
between approximately 10,000 and approximately 200,000 centiPoise;
between approximately 200,000 and approximately 5,000,000 centiPoise; and
between approximately 5,000,000 and 50,000,000 centiPoise.

16. The solar energy system of claim 11, wherein the resisting torque is linearly proportional to a rotational speed of the shaft of the spool.

17. The solar energy system of claim 16, wherein the resisting torque is linearly proportional to the rotational speed of the shaft of the spool according to the equation
τ₁=τ₂ω₁/ω₂.,
where τ₁ is the torque resisting rotational movement of the shaft; τ₂ is the torque at the first frequency; ω₁ is a rotational speed of the shaft due to the toque at the second frequency; and ω₂ is a rotational speed of the shaft due to the torque at the first frequency.

18. The solar energy system of claim 17, wherein the first frequency is approximately 3.6*10⁻⁵ radians per second.

19. The solar energy system of claim 17, wherein the second frequency is between approximately 0.5 Hz and 5 Hz.

20. The solar energy system of claim 1, further comprising a controller communicably coupled to the actuator assembly, the controller configured to drive the actuator assembly based on a position of the Sun relative to the surface of the solar energy member.

21. A heliostat control assembly, comprising:
a support member configured to be secured to a substantially fixed location;
a heliostat mirror mounted to the support member and comprising a reflective surface operable to face toward the Sun and reflect solar energy towards a solar energy receiver;
an actuator assembly configured to periodically apply a substantially static load to move the heliostat mirror in accordance with movement of the Sun; and
a damper assembly comprising:
a spool comprising a shaft configured to rotate to reactively release and retract a cable about the spool in response to changes in the substantially static load, and to maintain the cable at a substantially fixed length released from the spool in response to a dynamic load intermittently received by the heliostat mirror, wherein the cable is coupled to the heliostat mirror;
a viscous damper coupled to the shaft of the spool, the viscous damper configured to resist rotary movement of the shaft to maintain the cable at the substantially fixed length released from the spool in response to the dynamic load intermittently received by the solar energy member;
a cable tensioning assembly coupled to the shaft and configured to apply a substantially constant torque on the shaft urging refraction of the cable around the spool; and
a housing configured to sealingly enclose at least a portion of the damper assembly.

22. The heliostat control assembly of claim 21, wherein the damper assembly is supported by a terranean surface and the cable comprises:
a first end coupled to the heliostat mirror; and
a second end opposite the first end that is coupled to the spool of the damper assembly.

23. The heliostat control assembly of claim 22, wherein the housing is detachably coupled to the terranean surface.

24. The heliostat control assembly of claim 21, wherein the vertical support member is a first vertical support member and the heliostat mirror is a first heliostat mirror, and wherein the damper assembly is detachably secured to at least one of a second vertical support member or a second heliostat mirror, and the cable is secured at a first end to a terranean surface and is secured at a second end opposite the first end to the spool of the damper assembly.

25. The heliostat control assembly of claim 21, wherein the cable tensioning assembly comprises at least one of:
a torsion spring configured to apply the substantially constant torque on the shaft; and
an actuator configured to apply the substantially constant torque on the shaft.

26. The heliostat control assembly of claim 25, wherein the actuator is the actuator assembly, and wherein the actuator assembly is configured to rotate the spool based on the substantially static load to reactively release and retract the cable about the spool.

27. The heliostat control assembly of claim 26, wherein rotation of the spool based on the steady state load moves the heliostat mirror about at least one of:
a first axis to adjust an azimuth position of the heliostat mirror; or
a second axis to adjust an elevation position of the heliostat mirror.

28. The heliostat control assembly of claim 21, wherein the viscous damper comprises a fluid disposed between a first surface coupled to the damper assembly and a second surface coupled to the shaft, such that a torque resisting rotational movement of the shaft is created based on a viscous force acting between the first and second surfaces due to the fluid.

29. The heliostat control assembly of claim 21, further comprising a controller communicably coupled to the actuator assembly, the controller configured to drive the actuator assembly based on a position of the Sun relative to the reflective surface of the heliostat mirror.

30. The heliostat control assembly of claim 21, wherein the dynamic load comprises a wind load on at least a portion of the heliostat mirror.

31. A method for controlling a solar energy system comprising a solar energy member, a vertical support post, and a damper assembly, the method comprising:
determining, with a controller, to move a solar energy member from a first position to a second position different than the first position;
operating an actuator assembly to apply a substantially static torque to the solar energy member to move the solar energy member to the second position;
in response to the substantially static torque, reactively releasing or retracting a portion of a cable about a spool of the damper assembly during movement of the solar energy member to the second position, wherein the cable is coupled to the solar energy member; and
in response to a dynamic torque on the solar energy system, resisting rotational movement of the spool by a viscous damper of the damper assembly to substantially prevent release of the cable from the spool.

32. The method of claim 31, further comprising:
applying a substantially constant torque on the shaft by a cable tensioning assembly;
urging retraction of the cable around the spool based on the substantially constant torque.

33. The method of claim 31, wherein resisting rotational movement of the spool by a viscous damper of the damper assembly comprises generating a torque that resists rotational movement of the shaft based on a viscous force acting between a first surface and a second surface due to a fluid between the first and second surfaces, the first surface coupled to the damper assembly and the second surface coupled to the shaft.

34. The method of claim 33, wherein generating a torque that resists rotational movement of the shaft comprises generating a first torque proportional to a first rotational speed of the shaft of the spool caused by the substantially static torque to move the solar energy member to the second position.

35. The method of claim 33, wherein generating a torque that resists rotational movement of the shaft comprises generating a second torque proportional to a second rotational speed of the shaft of the spool caused by the dynamic torque on the solar energy system.

36. The method of claim 31, wherein determining to move the solar energy member to a second position different than the first position is based on a time of day, the method further comprising:
in response to determining to move the solar energy member, automatically transmitting a signal to the actuator assembly to move the solar energy member to the second position.
